(19) United States
(12) Patent Application Publication
(10) Pub. No.: US 2005/0139874 A1
(43) Pub. Date: Jun. 30, 2005

(54) Test patterns for semiconductor devices and methods of fabricating the same

(76) Inventor: Sang Gi Lee, Bucheon (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/021,428

(22) Filed: Dec. 23, 2004

(30) Foreign Application Priority Data
Dec. 24, 2003 (KR) 2003-0096993

(51) Int. Cl. H01L 21/8238; H01L 29/76; H01L 29/94; H01L 31/062; H01L 31/113; H01L 31/119

(52) U.S. Cl. 257/288; 438/228

(57) ABSTRACT

Test patterns for semiconductor devices and method for fabricating test patterns are disclosed. In a disclosed method, one well mask having multiple intervals of different widths is used to evaluate a well-isolation characteristic and to find an optimal sizing factor in an early stage of development. A disclosed test mask includes an n-well test mask and a p-well test mask for evaluating an isolation characteristic between an n-well and p-well formed on a semiconductor substrate, and a dummy layer inserted between the n-well test mask and the p-well test mask.

### FIELD OF THE DISCLOSURE

The present disclosure relates generally to semiconductor fabrication and, more particularly, to test patterns for semiconductor devices and methods of fabricating the same in which a distance between p-well and n-well patterns can be adjusted within one mask set to evaluate a well-isolation characteristic.

### BACKGROUND

Generally, the sizes of n-well and p-well mask patterns are adjusted in a sizing method when fabricating a mask for evaluating a well-isolation characteristic. However, it is difficult to set a reference appropriate for deciding how to apply a mask sizing.

A prior art test pattern for performing a well-isolation characteristic evaluation requires multiple modifications to the ion implantation conditions and multiple evaluations to obtain an optimized well-isolation characteristic of an appropriate size. These processes require many efforts and waste much time.

FIG. 1 is a combined diagram illustrating the layout and cross-section of a prior art well-isolation evaluating test pattern. A cross-sectional diagram of a semiconductor device is provided below the mask pattern.

Referring to FIG. 1, the illustrated test pattern includes an n-well mask 17 and a p-well mask 18.

An n-well 13, a p-well 14, and shallow trench isolation (STI) layers 12 are formed in the semiconductor device illustrated in FIG. 1. A p+ moat region 15 and an n+ moat region 16 are formed in the n-well 13 and the p-well 14, respectively.

The prior art well mask of FIG. 1 is used to form the n-well 13 and the p-well 14 after completing the formation of the STI layers 12 in the semiconductor substrate 11.

In fabricating an n-well mask 17 and a p-well mask 18, a sizing is used to increase/decrease a size by a prescribed value so that a fixed distance d1 lies between the n-well 13 and the p-well 14. In the illustrated example, the reference letter A in the layout indicates a well mask prior to applying the sizing and the reference letter A′ indicates the well mask after applying the sizing.

However, the well-isolation characteristic evaluation must be done with a fixed value. Further, a new test pattern should be fabricated for another well-isolation characteristic evaluation.

### BRIEF DESCRIPTION OF THE DRAWINGS

FIG. 1 is a combined diagram illustrating the layout and cross-section of a prior art well-isolation characteristic evaluation test pattern.

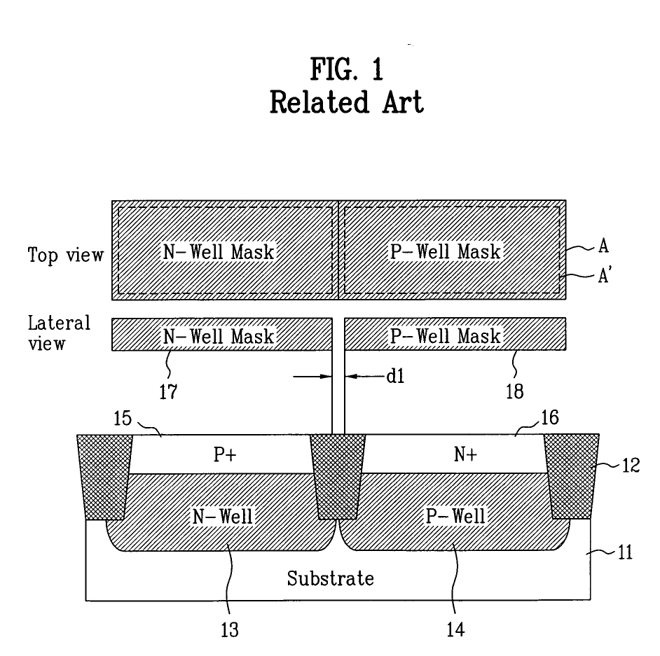

FIG. 2 is a combined diagram illustrating the layout and cross-section of an example well-isolation characteristic evaluation test pattern constructed in accordance with the teachings of the present invention.

### DETAILED DESCRIPTION

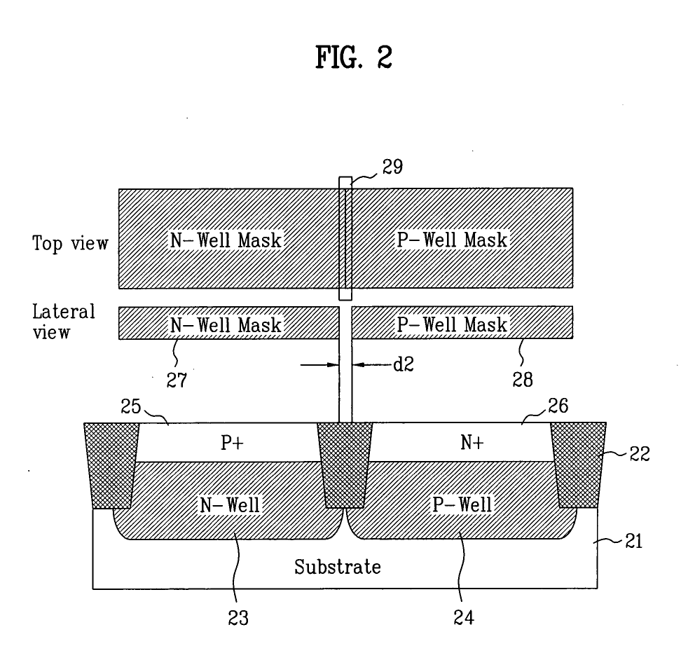

FIG. 2 is a combined diagram illustrating the layout and cross-section of an example well-isolation characteristic evaluation test pattern constructed in accordance with the teachings of the present invention. A cross-sectional diagram of an example semiconductor device is also included in FIG. 2.

Referring to FIG. 2, an n-well 23, a p-well 24, and shallow trench isolation (STI) layers 22 are formed in a semiconductor substrate 21 of the illustrated semiconductor device. A p+ moat region 25 and an n+ moat region 26 are formed in the n-well 23 and the p-well 24, respectively.

A well test mask constructed in accordance with the teachings of the present invention is used to form the n-well 23 and the p-well 24 after the formation of the STI layers 22 on the semiconductor substrate 21 is completed.

In forming the illustrated test pattern, a dummy layer 29 having a specific width d2 is inserted into the well-isolation evaluation test pattern. Later, in fabricating the mask, the interval d2 of the dummy layer 29 is cut out to leave a prescribed interval between the n-well mask 27 and the p-well mask 28.

In the example test pattern of FIG. 2, the dummy layer 29 having the specific width is inserted between the n-well mask 27 and the p-well mask 28. The dummy layer 29 is cut out to leave a prescribed interval d2 in-between the masks 27, 28. As a result, in carrying out ion implantation for forming the n-well 23 or the p-well 24, ions are not implanted via the interval d2. However, dopant diffusion in the n-well 23 or the p-well 24 forms a junction therein. As a result, a condition for securing an isolation characteristic between the n+ and p+ moat regions 25, 26 is achieved.

The optimal interval is set by evaluating the well-isolation characteristic using the above-configured mask test pattern, thereby saving time and cost.

Moreover, the above-described test pattern enables one mask set to be fabricated with multiple intervals of difference widths d2, thereby facilitating the finding of the optimal interval condition, (i.e., the optimal mask sizing factor), by evaluating the well-isolation characteristics for the various test patterns having the different intervals d2.

In view of the foregoing, persons of ordinary skill in the art will appreciate that test patterns having different intervals between the n-well and p-well masks can be fabricated in one mask set without fabricating an additional mask. As a result, the well mask sizing factor having the optimal well-isolation characteristic may be found in one fabrication process.

Accordingly, the fabrication time for a semiconductor device is reduced due to the ready availability of the well mask sizing factor having the optimal well-isolation characteristic.

From the foregoing, persons of ordinary skill in the art will also appreciate that test patterns and fabricating methods have been provided in which one well mask set is used to provide multiple intervals to evaluate a well-isolation characteristic and by which an optimal sizing factor can be found in an early stage of development.

A disclosed example test pattern includes: an n-well test mask and a p-well test mask for evaluating an isolation characteristic between an n-well and p-well formed on a semiconductor substrate. The test pattern also includes a dummy layer inserted between the n-well test mask and the p-well test mask.

Preferably, the dummy layer is cut by tooling in fabricating a next mask to leave a set-up interval between the n-well test mask and the p-well test mask.

Preferably, the dummy layer has multiple intervals of different widths on one mask set.

A disclosed example method of fabricating a test pattern for a semiconductor device includes: forming an n-well test mask and a p-well test mask for evaluating an isolation characteristic between an n-well and a p-well formed on a semiconductor substrate; inserting a dummy layer between the n-well test mask and the p-well test mask; and cutting the dummy layer to leave a setup interval between the n-well test mask and the p-well test mask.

Preferably, the dummy layer has multiple intervals of different widths on one mask set.

From the foregoing, persons of ordinary skill in the art will appreciate that, in order to secure an optimal condition by evaluating a well-isolation characteristic without using multiple mask sets, a dummy layer is inserted between an n-well mask and a p-well mask to forcibly form an interval between an n-well and a p-well by removing the dummy layer in subsequently fabricating a mask test pattern. The well-isolation characteristic is then evaluated using the mask test pattern to set an optimal interval. As a result, time and costs can be saved in fabricating a semiconductor device.

It is noted that this patent claims priority from Korean Application No. P2003-0096993, which was filed on Dec. 24, 2003, and which is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A test pattern for a semiconductor device comprising:
an n-well test mask and a p-well test mask for evaluating an isolation characteristic between an n-well and p-well formed on a semiconductor substrate; and
a dummy layer inserted between the n-well test mask and the p-well test mask.

2. A test pattern as defined in claim 1, wherein the dummy layer is cut by tooling in fabricating a next mask to create an interval between the n-well test mask and the p-well test mask.

3. A test pattern as defined in claim 1, wherein the dummy layer has multiple intervals on one mask set.

4. A method of fabricating a test pattern in a semiconductor device comprising:
forming an n-well test mask and a p-well test mask for evaluating an isolation characteristic between an n-well and p-well formed on a semiconductor substrate;
inserting a dummy layer between the n-well test mask and the p-well test mask; and
cutting the dummy layer to create an interval between the n-well test mask and the p-well test mask.

5. A method as defined in claim 4, wherein the dummy layer has multiple intervals on one mask set.
